(19) United States
(12) Patent Application Publication
(10) Pub. No.: US 2013/0341184 A1
(43) Pub. Date: Dec. 26, 2013

(54) Co-Cr-Pt-B-Based Alloy Sputtering Target and Method for Producing Same

(71) Applicants: Yuto Morishita, Ibaraki (JP); Shin-ichi Ogino, Ibaraki (JP); Yuichiro Nakamura, Ibaraki (JP)

(72) Inventors: Yuto Morishita, Ibaraki (JP); Shin-ichi Ogino, Ibaraki (JP); Yuichiro Nakamura, Ibaraki (JP)

(73) Assignee: JX NIPPON MINING & METALS CORPORATION, Tokyo (JP)

(21) Appl. No.: 14/003,621

(22) PCT Filed: May 22, 2012
(86) PCT No.: PCT/JP2012/063071

§ 371 Date: Sep. 6, 2013

(30) Foreign Application Priority Data
Jun. 30, 2011 (JP) 2011-145999

(51) Int. Cl. C23C 14/16; C22F 1/16

(52) U.S. Cl. CPC C23C 14/165; C22F 1/16
USPC 204/298.13; 148/674; 148/707; 72/340

(57) ABSTRACT

Provided is a Co—Cr—Pt—B-based alloy sputtering target having no more than 10 cracks of 0.1 to 20 μm in a B-rich phase in a 100 μm×100 μm area (field of view). Additionally provided is a method for producing this Co—Cr—Pt—B-based alloy sputtering target including the steps of hot forging or hot rolling a Co—Cr—Pt—B-based alloy cast ingot, thereafter performing cold rolling or cold forging thereto at an elongation rate of 4% or less, and machining the ingot to prepare a target having no more than 10 cracks of 0.1 to 20 μm in a B-rich phase in a 100 μm×100 μm area (field of view), or, hot forging or hot rolling the ingot, thereafter quenching the ingot to −196° C. to 100° C., and machining the ingot to prepare a target. The target of the present invention has high magnetic flux density and few microcracks in a B-rich layer, and thus stabilizes discharge and minimizes arcing.

### BACKGROUND

The present invention relates to a Co—Cr—Pt—B-based alloy sputtering target suitable for producing magnetic recording media, and to a method for producing such a Co—Cr—Pt—B-based alloy sputtering target.

In recent years, Co—Cr—Pt—B-based alloy is being used as a sputtering target for forming magnetic recording media such as magnetic film of hard disks.

In order to form a film via the sputtering method, normally a target made from a positive electrode and a target made from a negative electrode are caused to face each other, and high voltage is applied between the substrate and the target under an inert gas atmosphere to generate an electric field.

Sputtering is performed based on the following principle; namely, due to the foregoing application of high voltage, the ionized electrons and inert gas collide to form a plasma, the positive ions in the plasma collide with the target (negative electrode) surface, constituent atoms of the target are thereby sputtered, and the sputtered atoms adhere to the opposing substrate surface to form a film.

As the foregoing sputtering method, there are, for instance, the radio frequency sputtering (RF) method, the magnetron sputtering method, and the DC (direct current) sputtering method, and the appropriate sputtering method is used in accordance with the target material or deposition conditions.

The Co—Cr—Pt—B-based alloy is used as the sputtering target for forming a magnetic film of a hard disk. Here, since a discharge will not occur during sputtering if the magnetic flux density of the sputtering target is low, the voltage during sputtering needs to be increased when the magnetic flux density is low. Nevertheless, if the voltage during sputtering is increased, there is a problem in that arcing is generated or voltage becomes unstable.

Thus, in order to increase the magnetic flux density, strain is often artificially introduced upon producing a target to increase the magnetic flux density.

Nevertheless, when the Co—Cr—Pt—B-based alloy is subject to cold rolling, a new problem was discovered in that micro-sized cracks (hereinafter referred to as “microcracks”) are generated in the B-rich layer in the alloy. The B-rich layer is brittle. As described later, these microcracks become the origin of arcing during sputtering, and cause the generation or nodules or particles.

Thus, it is only logical that a target with few microcracks is demanded. Nevertheless, with conventional technology, there is no recognition of the foregoing point as being a problem, and no means for solving such problem has been proposed.

Upon reviewing the conventional technologies, Patent Document 1 discloses a Co—Pt—B-based target containing 1≦B≦10 (at. %) and a method for producing such a target. With this production method, Patent Document 1 describes a hot rolling temperature of 800 to 1100° C., and performing heat treatment at 800 to 1100° C. for 1 hour or longer before the hot rolling process. Moreover, Patent Document 1 describes that, while hot rolling is difficult when B is contained, the generation of cracks of the ingot during hot rolling can be inhibited by controlling the temperature.

Nevertheless, Patent Document 1 does not in any way describe the relation of the magnetic flux density and B, or the problem regarding the generation of microcracks and the solution thereof.

Patent Document 2 discloses sputtering targets based on CoCrPt, CoCrPtTa, and CoCrPtTaZr containing B as an essential component. Patent Document 2 describes that, with this technology, the rolling properties can be improved by reducing the Cr—B-based intermetallic compound phase.

As the production method and production process, Patent Document 2 describes performing vacuum drawing at 1450° C., casting at a temperature of 1360° C., heating and retaining at 1100° C. for 6 hours, and subsequently performing furnace cooling. Specifically, first time: heating at 1100° C. for 60 minutes, and thereafter rolling at 2 mm/pass, second time onward: heating at 1100° C. for 30 minutes, and thereafter rolling up to 5 to 7 mm for each pass.

Nevertheless, Patent Document 2 does not in any way describe the relation of the magnetic flux density and B, or the problem regarding the generation of microcracks and the solution thereof.

Patent Document 3 discloses a Co—Cr—Pt—B-based alloy sputtering target comprising a fine cast structure in which the diameter of the dendrite branches is 100 μm or less, and the thickness of the layer of the eutectic structure part is 50 μm or less. Moreover, Patent Document 3 proposes subjecting the cast ingot to cold working of rolling or forging at 10% or less.

The object of this technology is to eliminate pores, and Patent Document 3 describes devising the cast process (using a Cu surface plate and a mold made of aluminum titanate), prescribing the metal tapping temperature, and additionally subjecting the cast ingot to cold working of rolling or forging at 10% or less as needed. Moreover, Patent Document 3 is able to achieve a maximum magnetic permeability (μmax) of 20 or less.

Nevertheless, Patent Document 3 does not in any way describe the problem regarding the generation of microcracks and the solution thereof.

Patent Document 4 and Patent Document 5 respectively disclose Co—Cr—Pt—B—X1-X2-X3 and Co—Cr—Pt—B—Au—X1-X2. While the documents offer some description of attempting to improve the brittleness of B based on additives, the method is not very clear. The two documents merely propose compositions, and do not disclose a specific production method. Moreover, Patent Document 4 and Patent Document 5 do not in any way describe the problem regarding the generation of microcracks and the solution thereof.

Patent Document 6 discloses a sputtering target having a fine and uniform structure by improving the casting process and improving the rolling process of Co—Cr—Pt—B-based alloy.

As the specific processes to be performed after casting, the ingot is subject to hot rolling at a rolling reduction of 1.33% and temperature of 1100° C. for each pass, and rolling is performed 48 times for causing the crystal grain size of the alloy to be 100 μm or less. The rolling rate in the foregoing case is 55% (rolling rate is roughly 45% to 65%). Nevertheless, Patent Document 6 does not in any way describe the relation of the magnetic flux density and B, or the problem regarding the generation of microcracks and the solution thereof.

Patent Document 7 discloses a Co—Cr—Pt—B-based alloy sputtering target comprising an island shape of a Co-rich phase and a B-rich phase based on a eutectic structure between island structures made from a Co-rich phase based on primary crystals. This technology aims to reduce the segregation and internal stress in the sputtering target based on hot rolling to obtain a fine and uniform rolled structure, and thereby improves the film quality and improves the product yield. Nevertheless, Patent Document 7 does not in any way describe the relation of the magnetic flux density and B, or the problem regarding the generation of microcracks and the solution thereof.
Patent Document 1: JP-A-2001-026860
Patent Document 2: JP-A-2001-181832
Patent Document 3: JP-A-2005-146290
Patent Document 4: JP-A-2006-4611
Patent Document 5: JP-A-2007-023378
Patent Document 6: JP-A-2008-23545
Patent Document 7: Japanese Patent No. 3964453

### SUMMARY OF THE INVENTION

### Problems to be Solved by the Invention

An object of the present invention is to obtain a Co—Cr—Pt—B-based alloy sputtering target having high magnetic flux density and few microcracks in a B-rich layer, and thus stabilize discharge during sputtering and additionally inhibit arcing originating from microcracks. The inhibition of arcing enables the prevention or inhibition of the generation of nodules or particles, and improvement in the product yield of deposition, and the present invention aims to obtain the foregoing effects.

### Means for Solving the Problems

In order to achieve the foregoing object, as a result of intense study, the present inventors discovered that it is possible to produce a Co—Cr—Pt—B-based alloy sputtering target, which is free from microcracks and made from a fine and uniform rolled structure, by adjusting an ingot structure made from a Co—Cr—Pt—B-based alloy based on the control of processing methods including precise rolling or forging and heat treatment, thereby form a high quality sputtered film, and considerably improve the production yield.

Based on the foregoing discovery, the present invention provides:

1) A Co—Cr—Pt—B-based alloy sputtering target, wherein number of cracks of 0.1 to 20 μm in a B-rich phase in a 100 μm×100 μm area (field of view) is 10 cracks or less.

The present invention additionally provides:

2) The Co—Cr—Pt—B-based alloy sputtering target according to 1) above made from Cr: 1 to 40 at %, Pt: 1 to 30 at %, B: 0.2 to 25 at %, and remainder being Co and unavoidable impurities.

The present invention additionally provides:

3) The Co—Cr—Pt—B-based alloy sputtering target according to 2) above further containing, as an additive element, one or more elements selected from Cu, Ru, Ta, Pr, Nb, Nd, Si, Ti, Y, Ge, and Zr in an amount of 0.5 at % or more and 20 at % or less.

The present invention additionally provides:

4) The Co—Cr—Pt—B-based alloy sputtering target according to any one of 1) to 3) above, wherein maximum magnetic permeability (μmax) in a horizontal direction relative to a sputter face is 20 or less.

The present invention additionally provides:

5) The Co—Cr—Pt—B-based alloy sputtering target according to any one of 1) to 4) above, wherein coercive force (Hc) in a horizontal direction relative to a sputter face is 35 Oe or more.

The present invention additionally provides:

6) The Co—Cr—Pt—B-based alloy sputtering target according to any one of 1) to 5) above, wherein relative density is 95% or higher.

The present invention additionally provides:

7) A method for producing a Co—Cr—Pt—B-based alloy sputtering target including the steps of hot forging or hot rolling a Co—Cr—Pt—B-based alloy cast ingot, thereafter performing cold rolling or cold forging thereto at an elongation rate of 4% or less, and machining the ingot to prepare a target having no more than 10 cracks of 0.1 to 20 μm in a B-rich phase in a 100 μm×100 μm area (field of view).

The present invention additionally provides:

8) A method for producing a Co—Cr—Pt—B-based alloy sputtering target including the steps of hot forging or hot rolling a Co—Cr—Pt—B-based alloy cast ingot, thereafter quenching the ingot to −196° C. to 100° C., and machining the ingot to prepare a target.

The present invention additionally provides:

9) The method for producing a Co—Cr—Pt—B-based alloy sputtering target according to 8) above, wherein the Co—Cr—Pt—B-based alloy cast ingot is hot forged or hot rolled, and thereafter water cooled.

The present invention additionally provides:

10) The method for producing a Co—Cr—Pt—B-based alloy sputtering target according to 8) above, wherein the Co—Cr—Pt—B-based alloy cast ingot is hot forged or hot rolled, and thereafter quenched with a blower fan.

The present invention additionally provides:

11) The method for producing a Co—Cr—Pt—B-based alloy sputtering target according to 8) above, wherein the Co—Cr—Pt—B-based alloy cast ingot is hot forged or hot rolled, and thereafter quenched with liquid nitrogen.

The present invention additionally provides:

12) The method for producing a Co—Cr—Pt—B-based alloy sputtering target according to any one of 7) to 11) above, wherein the Co—Cr—Pt—B-based alloy cast ingot is heated to 800° C. to 1100° C., and subject to hot rolling or hot forging of 15% or less.

The present invention additionally provides:

13) A method for producing a Co—Cr—Pt—B-based alloy sputtering target for producing the Co—Cr—Pt—B-based alloy sputtering target according to any one of 1) to 6) above based on the production method according to any one of 7) to 12) above.

The present invention yields a superior effect of being able to provide a Co—Cr—Pt—B-based alloy sputtering target having high magnetic flux density and few microcracks in a B-rich layer. It is thereby possible to stabilize discharge during sputtering and additionally inhibit arcing originating from microcracks. Consequently, the present invention additionally yields an effect of being able to effectively prevent or inhibit the generation of nodules or particles.

Moreover, the present invention yields a superior effect of being able to decrease segregation and internal stress in the Co—Cr—Pt—B-based alloy sputtering target and thereby obtain a fine and uniform rolled structure, and consequently form a high quality film as well as considerably improve the production yield.

### BRIEF DESCRIPTION OF THE DRAWINGS

FIG. 1 is an SEM micrograph showing the surface polished face of the target of the present invention and a representative example in which hardly any cracks are generated in the B-rich phase.

FIG. 2 is an SEM micrograph showing the surface polished face of the target as a Comparative Example and a representative example in which numerous cracks are generated in the B-rich phase.

### DETAILED DESCRIPTION OF THE INVENTION

As the materials of the Co—Cr—Pt—B-based alloy sputtering target of the present invention; representatively, there are the following: Co—Cr—Pt—B alloy made from Cr: 1 to 40 at %, Pt: 1 to 30 at %, B: 0.2 to 25 at %, and remainder being Co and unavoidable impurities; Co—Cr—Pt—B—Cu alloy made from Cr: 1 to 40 at %, Pt: 1 to 30 at %, B: 0.2 to 25 at %, Cu: 1 to 10 at %, B+Cu: 1.2 to 26 at %, and remainder being Co and unavoidable impurities, Co—Cr—Pt—B—Ta alloy made from Cr: 1 to 40 at %, Pt: 1 to 30 at %, B: 0.2 to 25 at %, Ta: 1 to 10 at %, B+Ta: 1.2 to 26 at %, and remainder being Co and unavoidable impurities; Co—Cr—Pt—B—Ru alloy made from Cr: 1 to 40 at %, Pt: 1 to 30 at %, B: 0.2 to 25 at %, Ru: 1 to 10 at %, B+Ru: 1.2 to 26 at %, and remainder being Co and unavoidable impurities, and Co—Cr—Pt—B—Pr alloy made from Cr: 1 to 40 at %, Pt: 1 to 30 at %, B: 0.2 to 25 at %, Pr: 1 to 10 at %, B+Pr: 1.2 to 26 at %, and remainder being Co and unavoidable impurities.

These materials are effective as a sputtering target for forming a magnetic film of hard disks.

In a sputtering target made from Co—Cr—Pt—B-based alloy containing B, the present invention provides a Co—Cr—Pt—B-based alloy sputtering target that achieved 10 or less cracks of 0.1 to 20 μm in a B-rich phase in a 100 μm×100 μm area (field of view).

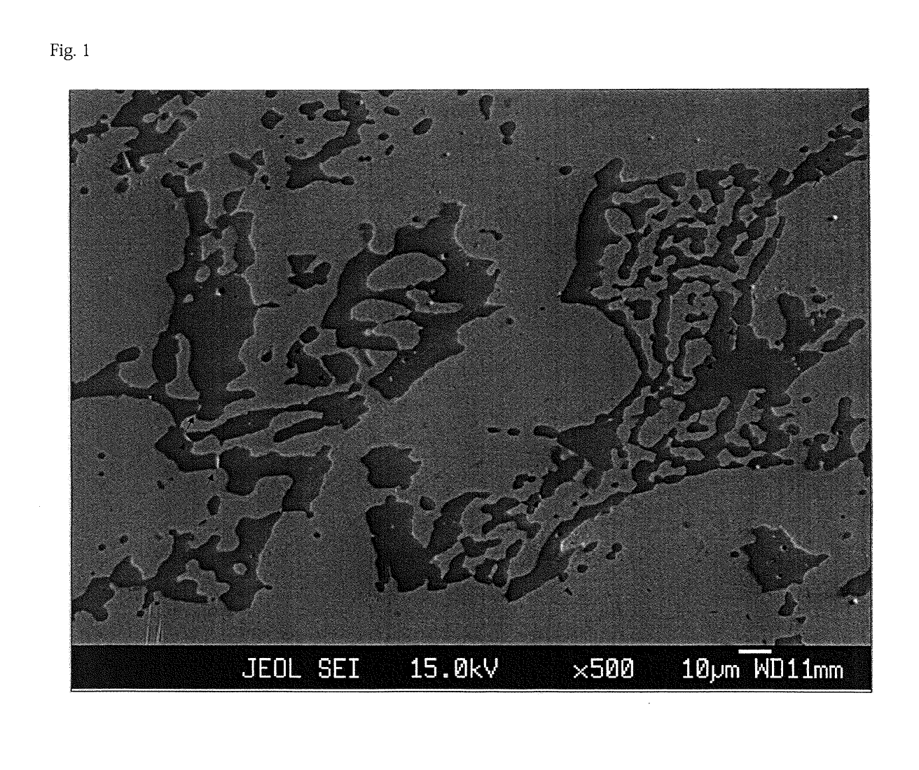

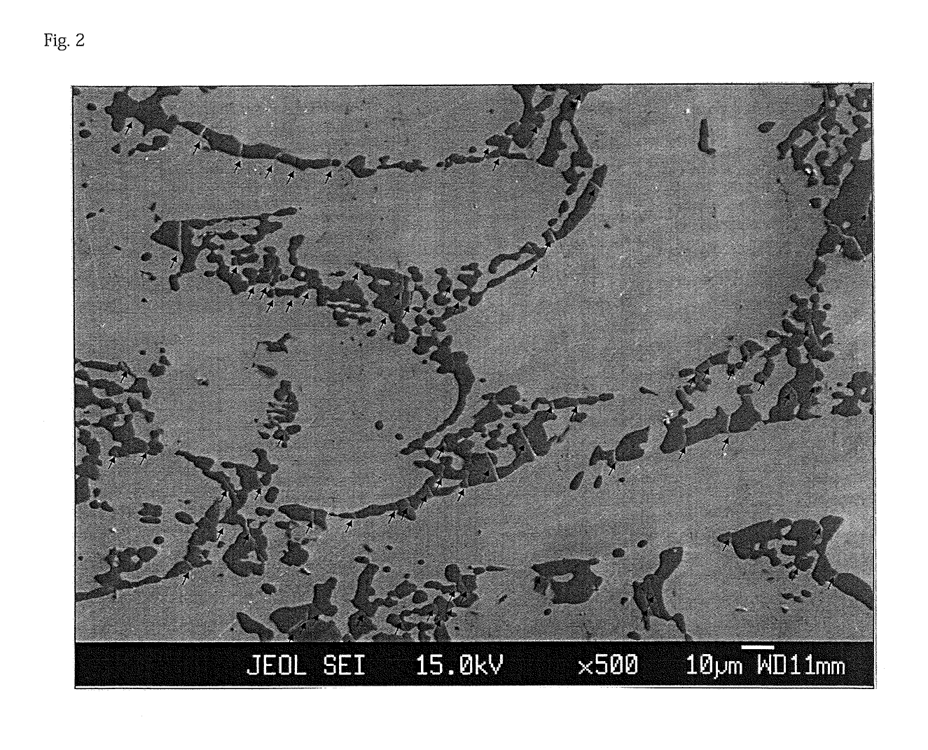

The term “B-rich phase” used herein refers to a region (matrix) containing more B than the peripheral region, and is separated into two phases; namely, a matrix phase and a B-rich phase. Microcracks of the sputtering target made from Co—Cr—Pt—B-based alloy exist in the B-rich phase. Moreover, while the shape and amount of the B-rich phase will change depending on the additive amount of B to other alloy-based metals, the B-rich phase often has a shape of cirrocumulus clouds (mackerel clouds, altocumulus clouds) in the matrix as shown in FIG. 1 and FIG. 2.

While cracks are normally formed in a crescent shape, linear shape (rod shape), or lightning shape, the size of the cracks referred to herein indicates the length upon linearly measuring the cracks from one end to the other end thereof. Arcing caused by cracks is affected by the length of such cracks. What is problematic is cracks of 0.1 to 20 μm; that is, microcracks.

Cracks of this size are hardly identified in the target structure, and conventionally there was no recognition that such microcracks cause the generation of arcing. When the cracks are less than 0.1 μm in size, they do not cause any particular problem in the generation of arcing. Moreover, while cracks that exceed 20 μm in size are problematic as a matter of course, these cracks rather lead to the fracture or crack of the target itself. Since the number of microcracks of 0.1 to 20 μm will further increase when cracks that exceed 20 μm in size are generated, in the present invention it could be said that the counting of microcracks of 0.1 to 20 μm is sufficient.

The present invention took particular note of the influence caused by microcracks of 0.1 to 20 μm. The number of microcracks of 0.1 to 20 μm becomes the problem. It is necessary to cause the number of microcracks in the B-rich phase in the 100 μm×100 μm area (field of view) to be 10 microcracks or less. When the number of microcracks exceeds 10 microcracks, it is not possible to inhibit the generation of arcing during the sputtering of the target.

Under circumstances where the number of microcracks in the B-rich phase of the target exceeds 10 microcracks, since macro-cracks exceeding 20 μm are often generated, such target does not correspond to the target of the present invention. Accordingly, the present invention effectively inhibits the generation of arcing by regulating the fine microcracks that could not be recognized conventionally.

There are several methods for inhibiting microcracks of 0.1 to 20 μm. In all cases, it is necessary to elaborately control the heating and rolling of the Co—Cr—Pt—B-based alloy target material. One such method is heating the Co—Cr—Pt—B-based alloy cast ingot to 800° C. to 1100° C., repeatedly hot forging or hot rolling the ingot at a rolling reduction of 15% or less, thereafter cold rolling or cold forging the ingot at an elongation rate of 4% or less, and additionally machining the ingot to prepare a Co—Cr—Pt—B-based alloy sputtering target.

Note that, since the temperature of the material decreases during the forging or rolling process, the heating to 800° C. to 1100° C. is performed on a case-by-case basis before performing the hot forging or hot rolling process. The heat treatment that is performed before the hot forging or hot rolling process is the same in the other processes described in this specification.

Since the generation of microcracks is also influenced by the B content, it is desirable to perform cold rolling or cold forging at an elongation rate of 4% or less in accordance with the B content.

The ingot is elongated into a plate shape after being subject to cold rolling or cold forging, and the elongation rate is set so that it does not exceed 4% as described above. Specifically, desirable conditions are to perform cold rolling or cold forging upon adjusting the elongation rate according to the B content so that the elongation rate is 4% or less in cases where the B content is up to 8 at %, the elongation rate is 2.5% or less in cases where the B content is up to 10 at %, and the elongation rate is 1.5% or less in cases where the B content is up to 12 at %.

Since the reduction of the elongation rate means the decrease in the cold working rate, the magnetic flux density will decrease slightly, but the rate of occurrence of microcracks can be considerably reduced.

The magnetic flux density is correlated to the magnetic permeability and coercive force of the sputter face direction. In other words, the magnetic flux density will increase as the magnetic permeability of the sputter face direction decreases or as the coercive force of the sputter face direction increases. Here, it is possible to obtain sufficient magnetic flux density that will not cause any abnormal discharge when the maximum magnetic permeability (μmax) in the horizontal direction relative to the sputter face is 20 or less, and the coercive force (Hc) in the horizontal direction relative to the sputter face is 35 Oe or more.

Cold rolling or cold forging is an effective means for applying strain to the Co—Cr—Pt—B-based alloy plate and increasing the magnetic flux density. Nevertheless, the application of strain beyond a certain level must be avoided since it will increase the number of microcracks. Performing the cold rolling or cold forging based on the elongation rate of the plate is an effective method for elaborately controlling the foregoing strain.

With conventional technology, it could be said that there was no technology that adopted an elongation rate of the foregoing level. Moreover, based on the control of the elongation rate, it is possible to cause the number of microcracks of 0.1 to 20 μm in a B-rich phase in a 100 μm×100 μm area (field of view) to be 10 microcracks or less.

The following method may be adopted as the method for increasing the magnetic flux density. In other words, heating a Co—Cr—Pt—B-based alloy cast ingot to 800° C. to 1100° C., repeatedly hot forging or hot rolling the ingot at a rolling reduction of 15% or less, immediately quenching the ingot to −196° C. to 100° C., and machining the ingot to prepare a Co—Cr—Pt—B-based alloy sputtering target.

As the quenching method in the foregoing case, immediately after the Co—Cr—Pt—B-based alloy cast ingot is subject to hot forging or hot rolling, the ingot is water cooled (or hardened). The water-cooling method is the most simple and effective quenching method.

Moreover, as another quenching method, the Co—Cr—Pt—B-based alloy cast ingot is subject to hot forging or hot rolling, and then quenched with a blower fan immediately thereafter. While the cooling effect is lower in comparison to water cooling, there is an advantage in that the equipment and handling are even simpler.

In addition, as another quenching method, the Co—Cr—Pt—B-based alloy cast ingot is subject to hot forging or hot rolling, and then quenched with liquid nitrogen immediately thereafter. In the foregoing case, the quenching effect is higher than water cooling, and magnetic properties can be improved. Since much of the effect of preventing microcracks depends on the temperature during rolling, if the conditions during rolling are the same, the effect will be the roughly the same as water cooling.

In all of the foregoing cases, a faster cooling rate is preferable, but it is effective to cool the ingot to 100° C. at least within 2 hours. It is also preferable to cool the ingot to normal temperature within 30 seconds in order to increase the quenching effect. In other words, this is because if it takes more than 2 hours to cool the ingot to 100° C. or lower, the strain that is introduced during the hot forging or hot rolling process will decrease due to the annealing effect, and the improvement in the magnetic flux density cannot be expected.

When cooling the ingot to normal temperature, the effect of causing the strain that was introduced during high temperature to remain can be yielded if the ingot is cooled in 30 seconds. Any subsequent quenching will increase costs, so it could be said that it is desirable to set 30 seconds as the upper limit, and cool the ingot in the neighborhood of 30 seconds.

By performing hot forging or hot rolling, cracks of the brittle B-rich phase can be prevented and, since the additional cold rolling or cold forging is not required, microcracks can be effectively inhibited. In other words, it is possible to cause microcracks of 0.1 to 20 μm in a B-rich phase in a 100 μm×100 μm area (field of view) to be 10 microcracks or less.

Moreover, by quench (hardening) the ingot, the strain that was introduced by way of hot forging or hot rolling can be maintained even at normal temperature, and the effect of increasing the magnetic flux density is yielded.

While there is no particular limitation in the hot rolling or hot forging of the Co—Cr—Pt—B-based alloy cast ingot, it could be said that, normally, it would be preferable to heat the ingot to 800° C. to 1100° C., and hot roll or hot forge the ingot at 15% or less. Hot rolling or hot forging is effective from the perspective of destroying the cast structure (dendrite structure), forming a uniform structure, controlling the shape and introducing strain. Introduction of strain is effective from the perspective of increasing the magnetic flux density.

With the present invention, as an additive element of the Co—Cr—Pt—B-based alloy sputtering target, one or more elements selected from Cu, Ru, Ta, Pr, Nb, Nd, Si, Ti, Y, Ge, and Zr may be contained in an amount of 0.5 at % or more and 20 at % or less. These elements yield the effect of increasing the magnetic flux density.

As specific examples, used may be, for instance, Co—Cr—Pt—B alloy made from Cr: 1 to 40 at %, Pt: 1 to 30 at %, B: 0.2 to 25 at %, and remainder being Co and unavoidable impurities; Co—Cr—Pt—B—Cu alloy made from Cr: 1 to 40 at %, Pt: 1 to 30 at %, B: 0.2 to 25 at %, Cu: 1 to 10 at %, B+Cu: 1.2 to 26 at %, and remainder being Co and unavoidable impurities, Co—Cr—Pt—B—Ta alloy made from Cr: 1 to 40 at %, Pt: 1 to 30 at %, B: 0.2 to 25 at %, Ta: 1 to 10 at %, B+Ta: 1.2 to 26 at %, and remainder being Co and unavoidable impurities, Co—Cr—Pt—B—Ru alloy made from Cr: 1 to 40 at %, Pt: 1 to 30 at %, B: 0.2 to 25 at %, Ru: 1 to 10 at %, B+Ru: 1.2 to 26 at %, and remainder being Co and unavoidable impurities, and Co—Cr—Pt—B—Pr alloy made from Cr: 1 to 40 at %, Pt: 1 to 30 at %, B: 0.2 to 25 at %, Pr: 1 to 10 at %, B+Pr: 1.2 to 26 at %, and remainder being Co and unavoidable impurities.

With a sputtering target produced with the foregoing materials, the maximum magnetic permeability (μmax) in the horizontal direction relative to the sputter face can be made to be 20 or less. Moreover, the coercive force (Hc) in the horizontal direction relative to the sputter face can also be made to be 35 Oe or more.

Moreover, the Co—Cr—Pt—B-based alloy sputtering target produced as described above can achieve a relative density or 95% or higher. Increase in the target density, namely, dense target is further effective for preventing the generation of particles.

### EXAMPLES

The present invention is now explained based on the Examples and Comparative Examples. Note that these Examples are merely illustrative, and the present invention is not in any way limited by these Examples. In other words, the present invention is limited only by the scope of claims, and covers the various modifications other than the Examples included in this invention.

### Example 1

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter cold rolled at an elongation rate of 1.0%, and additionally machined to obtain a target.

Specifically, while the hot rolling is repeatedly performed several ten times at a rolling reduction of 1 to 15% per pass, the hot rolling is adjusted so that the ultimate total rolling reduction becomes roughly 50 to 80%. In the ensuing explanation, the hot rolling was performed as described above in both the Examples and Comparative Examples.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 13, and the coercive force (Hc) was 49 Oe. And the number of microcracks of 0.1 to 20 μm in a B-rich phase in a 100 μm×100 μm area (field of view) was 0 microcracks. Note that the number of microcracks was measured by examining five arbitrary 100 μm×100 μm areas (fields of view) of the target, and taking the average value per area (field of view) of the number of microcracks existing therein. In the ensuing explanation, the number of microcracks was measured based on the foregoing method for both the Examples and Comparative Examples.

### Example 2

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter cold rolled at an elongation rate of 2.0%, and additionally machined to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 10, and the coercive force (Hc) was 63 Oe. And the number of microcracks of 0.1 to 20 μm in a B-rich phase in a 100 μm×100 μm area (field of view) was 8 microcracks.

### Example 3

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 900° C., hot rolled once at a rolling reduction of 10%, and thereafter immediately water cooled (quenched) by being held for 30 seconds or longer in water of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 11, and the coercive force (Hc) was 72 Oe. And the number of microcracks of 0.1 to 20 μm in a B-rich phase in a 100 μm×100 μm area (field of view) was 5 microcracks.

### Example 4

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately water cooled (quenched) by being held for 30 seconds or longer in water of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 12, and the coercive force (Hc) was 62 Oe. And the number of microcracks of 0.1 to 20 μm in a B-rich phase in a 100 μm×100 μm area (field of view) was 2 microcracks.

### Example 5

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1090° C., hot rolled once at a rolling reduction of 10%, and thereafter immediately water cooled (quenched) by being held for 30 seconds or longer in water of 20° C., and additionally machined, including surface polishing, to obtain a target.

In addition, the maximum magnetic permeability (μmax) and the maximum coercive force (Hcmax) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 14, and the coercive force (Hc) was 45 Oe. And the number of microcracks of 0.1 to 20 μm in a B-rich phase in a 100 μm×100 μm area (field of view) was 2 microcracks.

### Example 6

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately air cooled (quenched) by being held for 2 hours or longer in the atmosphere of a room temperature of 20° C., and additionally machined, including surface polishing, to obtain a target.

In addition, the maximum, magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 12, and the maximum coercive force (Hcmax) was 58 Oe. And the number of microcracks of 0.1 to 20 μm in a B-rich phase in a 100 μm×100 μm area (field of view) was 3 microcracks.

### Example 7

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1090° C., hot rolled once at a rolling reduction of 10%, and thereafter immediately retained (quenched) by being air cooled for 2 hours or longer in the atmosphere of a room temperature of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 17, and the coercive force (Hc) was 38 Oe. And the number of microcracks of 0.1 to 20 μm in a B-rich phase in a 100 μm×100 μm area (field of view) was 2 microcracks.

### Comparative Example 1

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter retained at 1000° C. to 1100° C. for 2 hours or longer and subsequently furnace cooled to 100° C. over a period of three and a half hours.

Subsequently, the hot rolled plate was machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL.

Consequently, the maximum magnetic permeability (μmax) in the horizontal direction relative to the sputter face of this target was 27, and the coercive force (Hc) was 11 Oe. And the number of microcracks of 0.1 to 20 μm in a B-rich phase in a 100 μm×100 μm area (field of view) was 0 microcracks. Accordingly, while the number of microcracks was 0 microcracks, since the magnetic permeability was high and the coercive force was low, the magnetic flux density decreased and it was confirmed that the resulting product is not suitable as a target.

### Comparative Example 2

A Co—Cr—Pt—B alloy raw material made from Cr: 14 at %, Pt: 18 at %, B: 10 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, and thereafter cold rolled at an elongation rate of 2.7%.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 10, and the coercive force (Hc) was 70 Oe. And the number of microcracks of 0.1 to 20 μm in a B-rich phase in a 100 μm×100 μm area (field of view) increased considerably to 30 microcracks. As a result, it was confirmed that, when the B content is contained up to 10 at %, cold rolling at an elongation rate exceeding 2.5% is undesirable.

Results of foregoing Examples 1 to 7 and Comparative Examples 1 and 2 are shown in Table 1.

TABLE 1
Co—14 Cr—18 Pt—10 B (at %)

| | | | Number of microcracks |
|---|---|---|---|
| | Magnetic | Coercive force | (microcracks/ |
| | permeability | (Oe) | 100 μm × 100 μm) |
| Example 1 | 13 | 49 | 0 |
| Example 2 | 10 | 63 | 8 |
| Example 3 | 11 | 72 | 5 |
| Example 4 | 12 | 62 | 2 |
| Example 5 | 13 | 45 | 2 |
| Example 6 | 12 | 58 | 3 |
| Example 7 | 17 | 38 | 2 |
| Comparative | 27 | 11 | 0 |
| Example 1 | | | |
| Comarative | 10 | 70 | 30 |
| Example 2 | | | |

### Example 8

A Co—Cr—Pt—B alloy raw material made from Cr: 15 at %, Pt: 18 at %, B: 8 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately water cooled (quenched) by being retained for 30 seconds or longer in water of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 15, and the coercive force (Hc) was 58 Oe. And the number of microcracks of 0.1 to 20 μm in a B-rich phase in a 100 μm×100 μm area (field of view) was 3 microcracks.

### Example 9

A Co—Cr—Pt—B alloy raw material made from Cr: 15 at %, Pt: 18 at %, B: 8 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately water cooled (quenched) by being retained for 30 seconds or longer in water of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 15, and the coercive force (Hc) was 62 Oe. And the number of microcracks of 0.1 to 20 μm in a B-rich phase in a 100 μm×100 μm area (field of view) was 4 microcracks.

### Example 10

A Co—Cr—Pt—B alloy raw material made from Cr: 15 at %, Pt: 18 at %, B: 8 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter, immediately retained (quenched) by being air cooled for 2 hours or longer in the atmosphere of a room temperature of 20° C., and additionally machined, including surface polishing, to obtain a target.

In addition, the maximum magnetic permeability (μmax) and the coercive force (Hc) in the horizontal direction relative to the sputter face of this target were measured. Moreover, the number of microcracks was measured using FE-EPMA (model number: JXA-8500F) manufactured by JEOL. Consequently, the maximum magnetic permeability (μmax) in the horizontal direction relative to the sputter face of this target was 15, and the coercive force (Hc) was 55 Oe. And the number of microcracks of 0.1 to 20 μm in a B-rich phase in a 100 μm×100 μm area (field of view) was 3 microcracks.

### Comparative Example 3

A Co—Cr—Pt—B alloy raw material made from Cr: 15 at %, Pt: 18 at %, B: 8 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt.

Subsequently, the ingot was heated to 800° C. to 1100° C., repeatedly hot rolled at a rolling reduction of 15% or less, thereafter cold rolled at an elongation rate of 4.2% and machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 9, and the coercive force (Hc) was 73 Oe. And the number of microcracks of 0.1 to 20 μm in a B-rich phase in a 100 μm×100 μm area (field of view) increased considerably to 18 microcracks. As a result, it was confirmed that, when the B content is contained up to 8 at %, cold rolling at an elongation rate exceeding 4% is undesirable.

Results of foregoing Examples 8 to 10 and Comparative Example 3 are shown in Table 2.

TABLE 2
Co—15 Cr—18 Pt—8 B (at %)

| | | | Number of microcracks |
|---|---|---|---|
| | Magnetic | Coercive force | (microcracks/ |
| | permeability | (Oe) | 100 μm × 100 μm) |
| Example 8 | 15 | 58 | 3 |
| Example 9 | 15 | 62 | 4 |
| Example 10 | 15 | 55 | 3 |
| Comarative | 9 | 73 | 18 |
| Example 3 | | | |

### Example 11

A Co—Cr—Pt—B alloy raw material made from Cr: 15 at %, Pt: 12 at %, B: 12 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately water cooled (quenched) by being retained for 30 seconds or longer in water of 20° C., and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 12, and the coercive force (Hc) was 72 Oe. And the number of microcracks of 0.1 to 20 μm in a B-rich phase in a 100 μm×100 μm area (field of view) was 3 microcracks.

### Example 12

A Co—Cr—Pt—B alloy raw material made from Cr: 15 at %, Pt: 12 at %, B: 12 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt. Subsequently, the ingot was heated to 800° C. to 1100° C., repeatedly hot rolled at a rolling reduction of 15% or less, thereafter heated to 1000° C., hot rolled once at a rolling reduction of 10%, and thereafter immediately quenched by being retained for 30 seconds or longer in liquid nitrogen, and additionally machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 15, and the coercive force (Hc) was 62 Oe. And the number of microcracks of 0.1 to 20 μm in a B-rich phase in a 100 μm×100 μm area (field of view) was 4 microcracks.

### Comparative Example 4

A Co—Cr—Pt—B alloy raw material made from Cr: 15 at %, Pt: 12 at %, B: 12 at %, and remainder being Co and unavoidable impurities was subject to radio frequency (vacuum) melting. The resulting product was cast using a mold, which is configured by cobalt being set on a copper surface plate, at a temperature between melting point and melting point+100° C. to obtain an ingot of 200×300×30 mmt.

Subsequently, the ingot was heated to 800° C. to 1100° C., repeatedly hot rolled at a rolling reduction of 15% or less, thereafter cold rolled at an elongation rate of 1.7% and machined, including surface polishing, to obtain a target.

In addition, the maximum magnetic permeability (μmax) and the coercive force (Hc) in the horizontal direction relative to the sputter face of this target were measured using a B-H meter (BHU-6020) manufactured by Riken Denshi. Moreover, the number of microcracks was measured using FE-EPMA (model number: JXA-8500F) manufactured by JEOL. Consequently, the maximum magnetic permeability (μmax) in the horizontal direction relative to the sputter face of this target was 8, and the coercive force (Hc) was 91 Oe. And the number of microcracks of 0.1 to 20 μm in a B-rich phase in a 100 μm×100 μm area (field of view) increased considerably to 22 microcracks. As a result, it was confirmed that, when the B content is contained up to 12 at %, cold rolling at an elongation rate exceeding 1.5% is undesirable.

Results of foregoing Examples 11 and 12 and Comparative Example 4 are shown in Table 3.

TABLE 3
Co—15 Cr—12 Pt—12 B (at %)

| | | | Number of microcracks |
|---|---|---|---|
| | Magnetic | Coercive force | (microcracks/ |
| | permeability | (Oe) | 100 μm × 100 μm) |
| Example 11 | 12 | 72 | 3 |
| Example 12 | 14 | 73 | 3 |
| Comarative | 8 | 91 | 22 |
| Example 4 | | | |

### INDUSTRIAL APPLICABILITY

The present invention yields a superior effect of being able to provide a Co—Cr—Pt—B-based alloy sputtering target having high magnetic flux density and few microcracks in a B-rich layer. It is thereby possible to stabilize discharge during sputtering and additionally inhibit arcing originating from microcracks. Consequently, the present invention further yields an effect of being able to effectively prevent or inhibit the generation of nodules or particles.

Moreover, the present invention yields a superior effect of being able to decrease segregation and internal stress in the Co—Cr—Pt—B-based alloy sputtering target and thereby obtain a fine and uniform rolled structure, and consequently form a high quality film as well as considerably improve the production yield.

As described above, since the present invention can obtain a Co—Cr—Pt—B-based alloy thin film having superior characteristics based on a target for use in forming a thin film of electronic components, this thin film is particularly suitable as a magnetic film of hard disks.

1. A Co—Cr—Pt—B-based alloy sputtering target, wherein number of cracks of 0.1 to 20 μm in a B-rich phase in a 100 μm×100 μm area (field of view) is 10 cracks or less.

2. The Co—Cr—Pt—B-based alloy sputtering target according to claim 1 made from Cr: 1 to 40 at %, Pt: 1 to 30 at %, B: 0.2 to 25 at %, and remainder being Co and unavoidable impurities.

3. The Co—Cr—Pt—B-based alloy sputtering target according to claim 2 further containing, as an additive element, one or more elements selected from Cu, Ru, Ta, Pr, Nb, Nd, Si, Ti, Y, Ge, and Zr in an amount of 0.5 at % or more and 20 at % or less.

4. The Co—Cr—Pt—B-based alloy sputtering target according to claim 3, wherein maximum magnetic permeability (max) in a horizontal direction relative to a sputter face is 20 or less.

5. The Co—Cr—Pt—B-based alloy sputtering target according to claim 4, wherein coercive force (Hc) in a horizontal direction relative to a sputter face is 35 Oe or more.

6. The Co—Cr—Pt—B-based alloy sputtering target according to claim 5, wherein relative density is 95% or higher.

7. A method for producing a Co—Cr—Pt—B-based alloy sputtering target including the steps of hot forging or hot rolling a Co—Cr—Pt—B-based alloy cast ingot, thereafter performing cold rolling or cold forging thereto at an elongation rate of 4% or less, and machining the ingot to prepare a target having no more than 10 cracks of 0.1 to 20 μm in a B-rich phase in a 100 μm×100 μm area (field of view).

8. A method for producing a Co—Cr—Pt—B-based alloy sputtering target including the steps of hot forging or hot rolling a Co—Cr—Pt—B-based alloy cast ingot, thereafter quenching the ingot to −196° C. to 100° C., and machining the ingot to prepare a target.

9. The method for producing a Co—Cr—Pt—B-based alloy sputtering target according to claim 8, wherein the Co—Cr—Pt—B-based alloy cast ingot is hot forged or hot rolled, and thereafter water cooled.

10. The method for producing a Co—Cr—Pt—B-based alloy sputtering target according to claim 8, wherein the Co—Cr—Pt—B-based alloy cast ingot is hot forged or hot rolled, and thereafter quenched with a blower fan.

11. The method for producing a Co—Cr—Pt—B-based alloy sputtering target according to claim 8, wherein the Co—Cr—Pt—B-based alloy cast ingot is hot forged or hot rolled, and thereafter quenched with liquid nitrogen.

12. The method for producing a Co—Cr—Pt—B-based alloy sputtering target according to claim 8, wherein the Co—Cr—Pt—B-based alloy cast ingot is heated to 800° C. to 1100° C., and subject to hot rolling or hot forging of 15% or less.

13. A method for producing a Co—Cr—Pt—B-based alloy sputtering target according to claim 8, wherein a number of cracks of 0.1 to 20 μm in a B-rich phase in a 100 μm×100 μm area of the sputtering target is 10 cracks or less.

14. The Co—Cr—Pt—B-based alloy sputtering target according to claim 1 further containing, as an additive element, one or more elements selected from Cu, Ru, Ta, Pr, Nb, Nd, Si, Ti, Y, Ge, and Zr in an amount of 0.5 at % or more and 20 at % or less.

15. The Co—Cr—Pt—B-based alloy sputtering target according to claim 1, wherein maximum magnetic permeability (μmax) in a horizontal direction relative to a sputter face is 20 or less.

16. The Co—Cr—Pt—B-based alloy sputtering target according to claim 1, wherein coercive force (Hc) in a horizontal direction relative to a sputter face is 35 Oe or more.

17. The Co—Cr—Pt—B-based alloy sputtering target according to claim 1, wherein relative density is 95% or higher.
